(19) United States
(12) Patent Application Publication
(10) Pub. No.: US 2010/0189283 A1
(43) Pub. Date: Jul. 29, 2010

(54) TONE EMPHASIZING DEVICE, TONE EMPHASIZING METHOD, TONE EMPHASIZING PROGRAM, AND RECORDING MEDIUM

(75) Inventor: Ichiro Sugai, Saitama (JP)

Correspondence Address: FOLEY AND LARDNER LLP;SUITE 500, 3000 K STREET NW, WASHINGTON, DC, 20007, US

(73) Assignee: Pioneer Corporation

(21) Appl. No.: 12/667,138

(22) PCT Filed: Jul. 3, 2007
(86) PCT No.: PCT/JP2007/063300

§ 371 Date: Jan. 26, 2010

(51) Int. Cl. H03G 9/00

(52) U.S. Cl. 381/102

(57) ABSTRACT

A tone emphasizing device includes a tone emphasizing unit that includes a level detecting unit that detects a fundamental tone level of a tone of a given pitch included in an original tone reproduced by a data player; an extracting unit that extracts frequency components of a fundamental tone and overtones from the original tone; a frequency correcting unit that eliminates, from the extracted frequency components, frequency components equal to or lower than the fundamental tone and frequency components equal to or higher than an overtone included in the tone of the given pitch; and a level adjusting unit that adjusts, according to results obtained by the level detecting unit, a level of the corrected tone. The tone emphasizing device further includes an amplifying unit that amplifies to a desired level, the tone having an adjusted level; and an adding unit that adds to the original tone, the amplified tone.

### TECHNICAL FIELD

The present invention relates to a tone emphasizing device, a tone emphasizing method, a tone emphasizing program, and a recording medium for emphasizing a tone(s) of a given pitch or within a given range of pitch. However, use of this invention is not limited to the tone emphasizing device, the tone emphasizing method, the tone emphasizing program, and recording medium described above.

### BACKGROUND ART

Conventionally, a data (music) player or a stereo unit includes a tone controller (equalizer) that emphasizes a given range of pitch. The tone controller boosts tones within the range of pitch to be emphasized. More specifically, a sound quality controller disclosed in Patent Document 1, for example, has a function of changing frequency characteristics to achieve a desired sound quality by a digital equalizer.

Patent Document 1: Japanese Examined Patent Publication No. H6-50810

### DISCLOSURE OF INVENTION

### Problem to be Solved by the Invention

However, it has been pointed out as a problem that, since the technology disclosed in Patent Document 1 merely boosts a given range of pitch as described above, the balance of upper harmonics of a tone can be lost and/or undesired tone components can be emphasized, thereby making the result sound unnatural to a listener.

### Means for Solving Problem

A tone emphasizing device according to the invention of claim 1 includes a tone emphasizing unit that includes a level detecting unit that detects a fundamental tone level of a tone of a given pitch included in an original tone reproduced by a data player; an extracting unit that extracts frequency components of a fundamental tone and overtones from the original tone; a frequency correcting unit that eliminates, from the frequency components extracted by the extracting unit, frequency components equal to or lower than the fundamental tone and frequency components equal to or higher than an overtone included in the tone of the given pitch; and a level adjusting unit that adjusts, according to a result of detection by the level detecting unit, a level of the tone corrected by the frequency correcting unit. The tone emphasizing device further includes an amplifying unit that amplifies to a desired level, the tone for which level has been adjusted by the level adjusting unit; and an adding unit that adds to the original tone, the tone amplified by the amplifying unit.

A tone emphasizing method according to the invention of claim 7 includes a tone emphasizing step that includes a level detecting step of detecting a fundamental tone level of a tone of a given pitch included in an original tone reproduced by a data player; an extracting step of extracting frequency components of a fundamental tone and overtones from the original tone; a frequency correcting step of eliminating, from the frequency components extracted at the extracting step, frequency components equal to or lower than the fundamental tone and frequency components equal to or higher than an overtone included in the tone of the given pitch; and a level adjusting step of adjusting, according to a result of detection at the level detecting step, a level of the tone corrected at the frequency correcting step. The tone emphasizing method further includes an amplifying step of amplifying to a desired level, the tone for which level has been adjusted at the level adjusting step; and an adding step of adding to the original tone, the tone amplified at the amplifying step.

A tone emphasizing program according to the invention of claim 8 causes a computer to execute the tone emphasizing method according to claim 7.

A recording medium according to the invention of claim 9 stores therein the tone emphasizing program according to claim 8 such that the tone emphasizing program can be read by a computer.

### BRIEF DESCRIPTION OF DRAWINGS

FIG. 1 is a block diagram depicting a functional configuration of a tone emphasizing device according to the present embodiment;

FIG. 2 is a flowchart of processing performed by the tone emphasizing device according to the present embodiment;

FIG. 3 is a block diagram depicting a configuration of a stereo system according to the present example;

FIG. 4 is a block diagram depicting a configuration of a signal processor;

FIG. 5 is a block diagram depicting a configuration of a signal processor that includes plural tone emphasizing units;

FIG. 6 is a block diagram depicting a configuration of a signal processor that processes plural tones by a common equalizing unit;

FIG. 7 is a block diagram depicting an exemplary configuration of a level detecting unit;

FIG. 8 is a block diagram depicting an exemplary configuration of a comb filter unit;

FIG. 9 is a chart depicting an example of filter characteristics of the comb filter;

FIG. 10 is a block diagram depicting an exemplary configuration of an equalizing unit;

FIG. 11 is a chart depicting an example of gain characteristics of a level changing unit; and

FIG. 12 is a flowchart of a procedure of tone emphasizing processing performed by the tone emphasizing unit.

### EXPLANATIONS OF LETTERS OR NUMERALS

100 tone emphasizing device

101 level detecting unit

102 extracting unit

103 frequency correcting unit

104 level adjusting unit

105 amplifying unit

106 adding unit

110 tone emphasizing unit

301 sound source player

302 signal processor

303 amplifier

304 speaker

### BEST MODE(S) FOR CARRYING OUT THE INVENTION

Exemplary embodiments of a tone emphasizing device, a tone emphasizing method, a tone emphasizing program, and a recording medium according to the present invention is described in detail with reference to the accompanying drawings.

### (Functional Configuration of Tone Emphasizing Device)

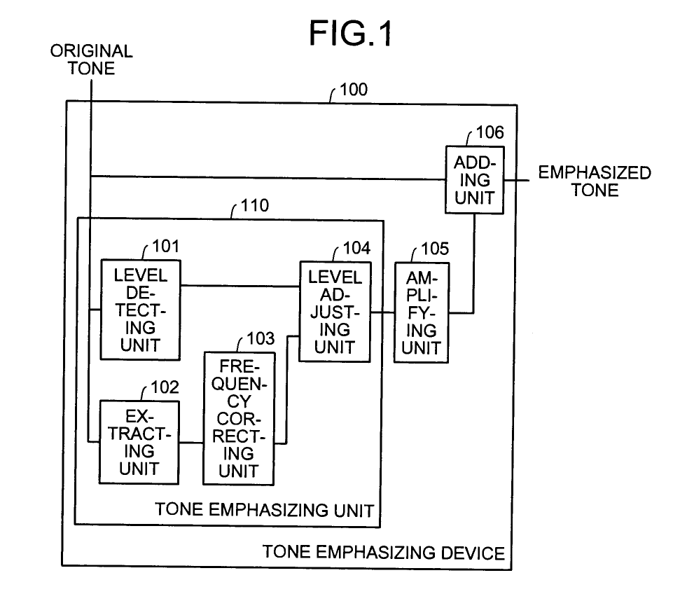

A functional configuration of a tone emphasizing device according to an embodiment is described first. FIG. 1 is a block diagram depicting a functional configuration of the tone emphasizing device according to the present embodiment. As depicted in FIG. 1, a tone emphasizing device 100 is configured to include a level detecting unit 101, an extracting unit 102, a frequency correcting unit 103, a level adjusting unit 104, an amplifying unit 105, and an adding unit 106. In particular, the level detecting unit 101, the extracting unit 102, the frequency correcting unit 103, and the level adjusting unit 104 form a tone emphasizing unit 110.

The tone emphasizing device 100 emphasizes a tone(s) of a given pitch(es) included in the original tone reproduced by a data player such as a music player. An emphasized tone in which the given pitch is emphasized is reproduced by adding the tone emphasized by the tone emphasizing device 100 to the original tone. Each functional unit for emphasizing the tone is described below.

The level detecting unit 101 detects the fundamental tone level of the tone of the given pitch included in the original tone reproduced by the music player. The pitch can be arbitrarily set by a user and/or an upper system. Alternatively, the level detecting unit 101 may detect, for example, the fundamental tone levels of tones that are specified based on the center frequency of a tone of a given pitch and a given range of pitch.

If the range of the fundamental tone is set as described above, the broader the frequency range within which one level detecting unit 101 detects the fundamental tone level becomes, the greater the number of pitches included therein becomes. As a result, if all pitches constituting the original tone are to be the target of the detection, broadening of the frequency range reduces the number of times processing is executed for emphasizing each pitch within a given range of pitch. Thus, the range of the fundamental tone can be set to be broad if it is desirable to reduce the number of times of the tone emphasizing process is executed.

The extracting unit 102 extracts, from the original tone reproduced by the music player, frequency components of the fundamental tone and the overtones. In other words, the extracting unit 102 extracts a given fundamental tone and the upper harmonic components thereof from the original tone.

More specifically, the extracting unit 102 is configured with a comb filter that extracts frequency components of frequencies that are integer multiples of the frequency of the fundamental tone of a tone.

The frequency correcting unit 103 eliminates, from the frequency components extracted by the extracting unit 102, frequency components equal to or lower than the fundamental tone and frequency components equal to or higher than an overtone. This elimination process removes noise components from the tone. In addition to eliminating the frequency components as described above, the frequency correcting unit 103 may have a function of amplifying or attenuating a given frequency range.

The level adjusting unit 104 adjusts, based on the result of detection by the level detecting unit 101, the level of the tone that has been corrected by the frequency correcting unit 103. More specifically, the level adjusting unit 104 amplifies the tone corrected by the frequency correcting unit 103 in proportion to the fundamental tone level detected by the level detecting unit 101.

The amplifying unit 105 amplifies to a desired level, the tone for which the level has been adjusted by the level adjusting unit 104. The degree of the amplification may be adjusted by the user and/or the upper system. The adding unit 106 adds to the original tone, the tone that has been amplified by the amplifying unit 105. Thus, the emphasized tone in which a tone of a given pitch is emphasized is output from the adding unit 106. The emphasized tone is reproduced by a player (not depicted) arranged downstream of the tone emphasizing device 100.

As described above, the level detecting unit 101, the extracting unit 102, the frequency correcting unit 103, and the level adjusting unit 104 form the tone emphasizing unit 110. Alternatively, the tone emphasizing device 100 may include plural tone emphasizing units 110 that emphasize tones of different pitches, respectively.

If the tone emphasizing device 100 includes plural tone emphasizing units 110, the amplifying unit 105 collectively amplifies plural tones, the levels of which have been adjusted by each level adjusting unit 104 of each tone emphasizing unit 110, to the desired level. The adding unit 106 collectively adds the tones that have been amplified by the amplifying unit 105 to the original tone.

In place of the frequency correcting unit 103 included in each tone emphasizing unit 110, the tone emphasizing device 100 may include, downstream of the tone emphasizing units 110, a common frequency correcting unit (not depicted) that corrects frequencies of tones of different pitches. In this case, the level adjusting unit 104 of each tone emphasizing unit 110 adjusts the level of the tone components extracted by the extracting unit 102 according to the result of detection by the level detecting unit 101.

### (Content of Processing Performed by Tone Emphasizing Device)

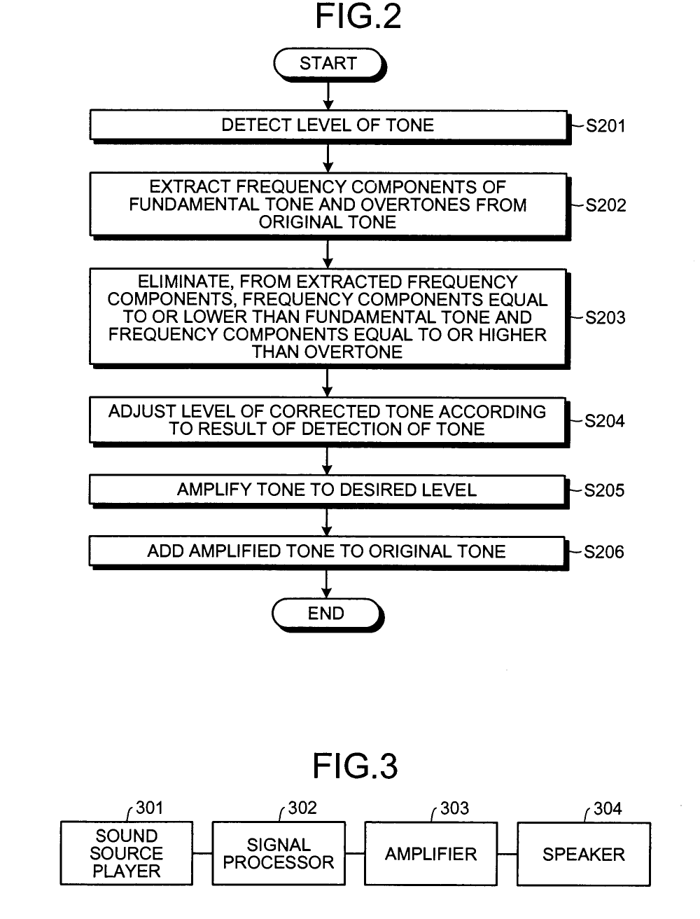

Processing performed by the tone emphasizing device is described next. FIG. 2 is a flowchart of processing performed by the tone emphasizing device according to the present embodiment. As depicted in the flowchart of FIG. 2, the level detecting unit 101 detects the level of the tone of the original tone (step S201). The extracting unit 102 extracts the frequency components of the fundamental tone and the overtones from the original tone of which level has been detected by the level detecting unit 101 (step S202).

The frequency correcting unit 103 eliminates, from the frequency components extracted at step S202, the frequency components equal to or lower than the fundamental tone and the frequency components equal to or higher than the overtone included in a given tone (step S203). The level adjusting unit 104 adjusts, according to the result of detection at step S201, the level of the tone that has been corrected by the frequency correcting unit 103 (step S204).

The amplifying unit 105 amplifies the level-adjusted tone to a desired level (step S205), the adding unit 106 adds the amplified tone to the original tone (step S206), and the processing ends. The tone emphasizing process described above is continuously performed as long as original tones are input, and newly input tones are subjected to the processing described at steps S202 to S206.

As described above, the tone emphasizing device 100 according to the present embodiment generates the emphasized tone by extracting, from the original tone, a given tone specified by the user and as the fundamental tone, the upper harmonic components of the tone, and performing desired amplification after eliminating noise. Thus, in contrast to the conventional art, the tone emphasizing device 100 reproduces tones such that a given pitch(es) is emphasized naturally without losing the balance of the upper harmonic components. Further, the tone emphasizing device 100 having plural tone emphasizing units 110 emphasizes tones of different pitches simultaneously.

### EXAMPLE

An example of the present invention is described below. In the following example, the tone emphasizing device 100 according to the embodiment described above is installed in a signal processor constituting a stereo system.

### (Configuration of Stereo System)

A stereo system according to the present example is described first. FIG. 3 is a block diagram depicting a configuration of the stereo system according to the present example. As depicted in FIG. 3, the stereo system is configured to include a sound source player 301, a signal processor 302, an amplifier 303, and a speaker 304. The sound source player 301, the signal processor 302, and the amplifier 303 may be configured with a digital signal processor (DSP) dedicated to music playback, or an analog device.

By using the signal processor 302, a user adjusts the signal for music reproduced by the sound source player 301. Here, a tone emphasizing process in which a given tone is emphasized by the signal processor 302 is described. The music signal emphasized by the signal processor 302 is input to the amplifier 303 as an emphasized tone signal. The emphasized tone signal is amplified by the amplifier 303 according to user setting, and subsequently output to the speaker 304. The speaker 304 outputs sound reproduced from the emphasized tone signal amplified by the amplifier 303.

### (Configuration of Signal Processor)

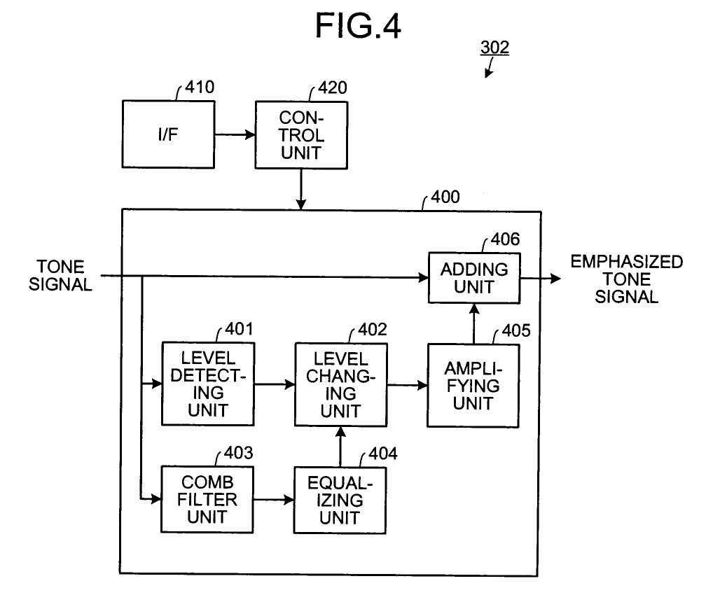

A configuration of the signal processor 302 is described next. FIG. 4 is a block diagram depicting a configuration of the signal processor. As depicted in FIG. 4, the signal processor 302 is configured by a tone emphasizing unit 404, an interface (I/F) 410, and a controller 420.

The tone emphasizing unit 400 is a functional unit that emphasizes a tone of a given pitch that is included in the music signal reproduced by the sound source player 301 and specified by the user. The I/F 410 functions as an interface for setting a tone to be emphasized, setting a mode, etc. through user operation. The controller 420 controls the operation of the functional units included in the tone emphasizing unit 400 to cause the tone emphasizing unit 400 to perform the tone emphasizing processing according to the setting set through the I/F 410.

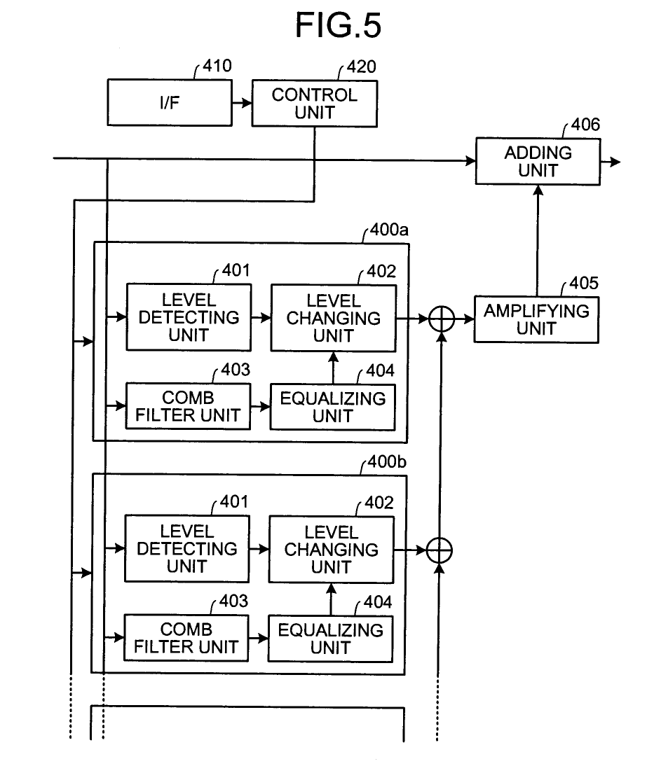

FIG. 5 is a block diagram depicting a configuration of a signal processor that includes plural tone emphasizing units. As depicted in FIG. 5, the signal processor 302 may include plural tone emphasizing units 400a to 400n. The tone emphasizing units 400a to 400n depicted in FIG. 5 have a function of emphasizing tones of different pitches.

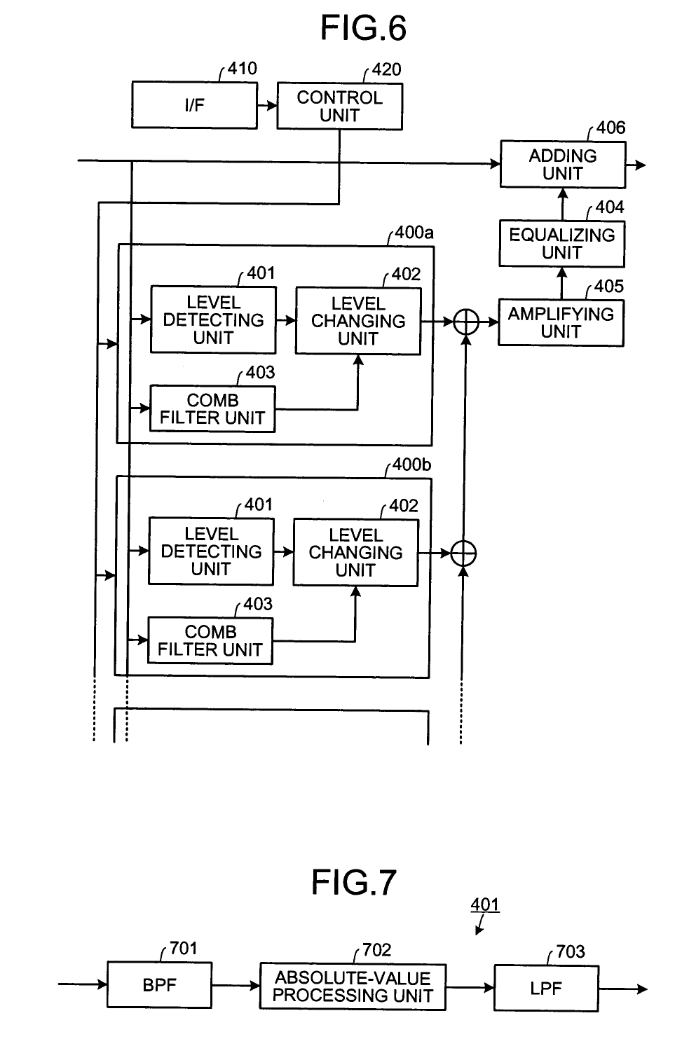

FIG. 6 is a block diagram depicting a configuration of a signal processor that processes plural tones by a common equalizing unit. As depicted in FIG. 6, when the signal processor 302 includes plural tone emphasizing units 400a to 400n, an equalizing unit 404 described below may be removed from each of the tone emphasizing units 400a to 400n and arranged downstream of the tone emphasizing units 400a to 400n as a common unit equalizing plural tones. The equalizing unit 404 depicted in FIG. 6 is arranged between an amplifying unit 405 and an adding unit 406; however, the equalizing unit 404 may be arranged between the tone emphasizing units 400a to 400n and the amplifying unit 405.

A specific configuration of the tone emphasizing unit 400 is described next. As depicted in FIG. 4, the tone emphasizing unit 400 is configured to include a level detecting unit 401, a level changing unit 402, a comb filter unit 403, the equalizing unit 404, the amplifying unit 405, and the adding unit 406. Here, functional units of the tone emphasizing unit 400 or the tone emphasizing units 400a to 400n depicted in FIGS. 4 and 5 is described; however, the basic operation of the following functional units is the same with respect to the tone emphasizing units 400a to 400n depicted in FIG. 6.

### Level Detecting Unit

FIG. 7 is a block diagram depicting an exemplary configuration of the level detecting unit. As depicted in FIG. 7, the level detecting unit 401 is configured by a bandpass filter (BPF) 701, an absolute-value processing unit 702, and a lowpass filter (LPF) 703. The BPF 701 transmits, from the music signal, a frequency component having the center frequency fc. The absolute-value processing unit 702 is configured with a half-wave rectifier, for example, and takes the absolute value from the frequency component that has passed through the BPF 701. The LPF 703 has a cutoff frequency set as fc/10, transmits frequency components equal to or lower than fc/10 from the absolute value taken by the absolute-value processing unit 702, and detects the level of the tone of the pitch fc. Alternatively, the level detecting unit 401 may detect the level by a digital filter capable of performing discrete Fourier transformation.

### Comb Filter Unit

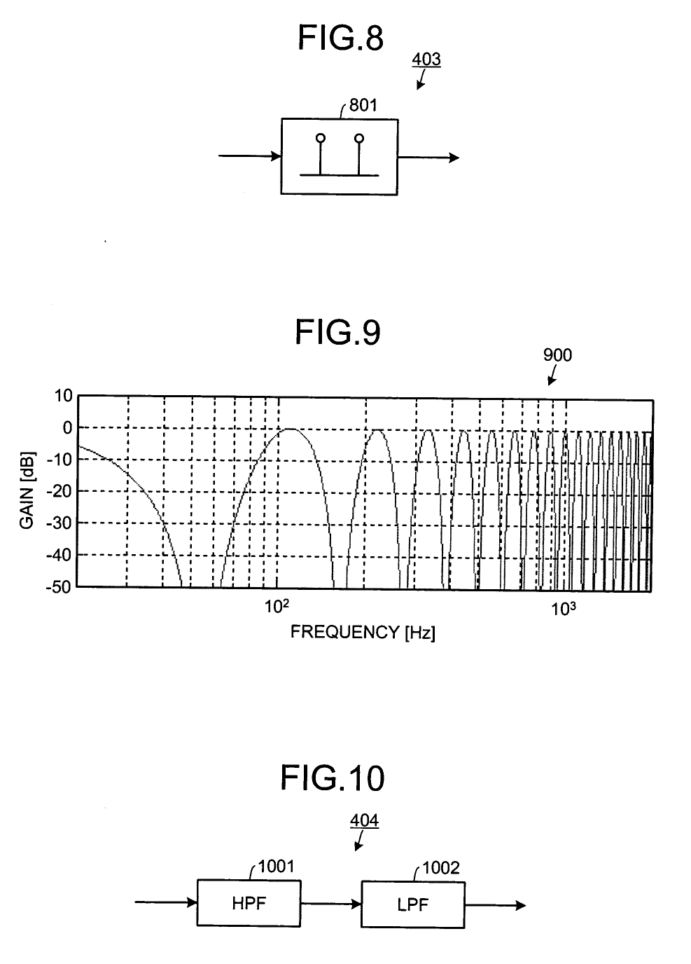

FIG. 8 is a block diagram depicting an exemplary configuration of the comb filter unit. As depicted in FIG. 8, the comb filter unit 403 includes a comb filter 801.

The comb filter 801 is a finite impulse response (FIR) filter with two taps for which time interval and level are set respectively as 1/fc and 0.5.

FIG. 9 is a chart depicting an example of the filter characteristics of the comb filter. The chart 900 depicted in FIG. 9 depicts the frequency-gain characteristics of the comb filter 801 when the fundamental tone is a tone of 110 Hz. As depicted in FIG. 9, the comb filter unit 403 transmits frequency components of the fundamental tone and the overtones, thereby extracting the fundamental tone and the upper harmonic components thereof.

### Equalizing Unit

FIG. 10 is a block diagram depicting an exemplary configuration of the equalizing unit. As depicted in FIG. 10, the equalizing unit 404 is configured by a highpass filter (HPF) 1001 and a lowpass filter (LPF) 1002. The HPF 1001 has a cutoff frequency set as fc/2, and cuts low frequency components equal to or lower than fc/2, i.e. noise equal to or lower than the fundamental tone, from the fundamental tone and the upper harmonic components output from the comb filer unit 403. The LPF 1002 has a cutoff frequency set as fc×5. Thus, through the LPF 1002, high frequency components equal to or higher than fc×5 (i.e. noise equal to or higher than a harmonic) are cut from the fundamental tone and the upper harmonic components.

### Level Changing Unit

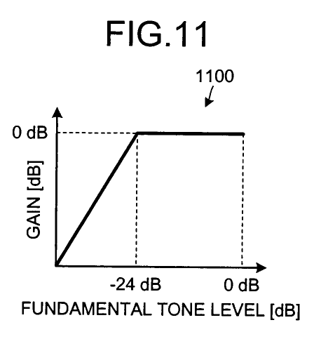

The level changing unit 402 is configured with a variable amplifier, and the gain thereof changes according to the output from the level detecting unit 401. More specifically, the level changing unit 402 adjusts the music signal, which has been winnowed to the fundamental tone and the upper harmonic components by the equalizing unit 404, to a level substantially equivalent to that of the original music signal input to the level detecting unit 401. FIG. 11 is a chart depicting an example of the gain characteristics of the level changing unit. The level changing unit 402 adjusts gain according to, for example, the characteristics indicated in the chart 1100 depicted in FIG. 11. The characteristics can be changed according to listening preferences of the user.

### Amplifying Unit and Adding Unit

The amplifying unit 405 is configured with a variable amplifier, and applies desired gain to the music signal output from the level changing unit 402. The adding unit 406 is configured with an adder, adds the amplified music signal to the original tone for output as an emphasized tone signal.

As described above, the tone emphasizing unit 400 is configured to extract and amplify not only the fundamental tone but also the upper harmonic components of a tone specified by the user. The cutoff frequencies of the filters constituting each functional unit of the tone emphasizing unit 400 described above are mere examples, and can be applied with other settings according to the utilization environment of the stereo system, characteristics of the speaker, etc..

### (Procedure of Tone Emphasizing Processing Performed by Signal Processor)

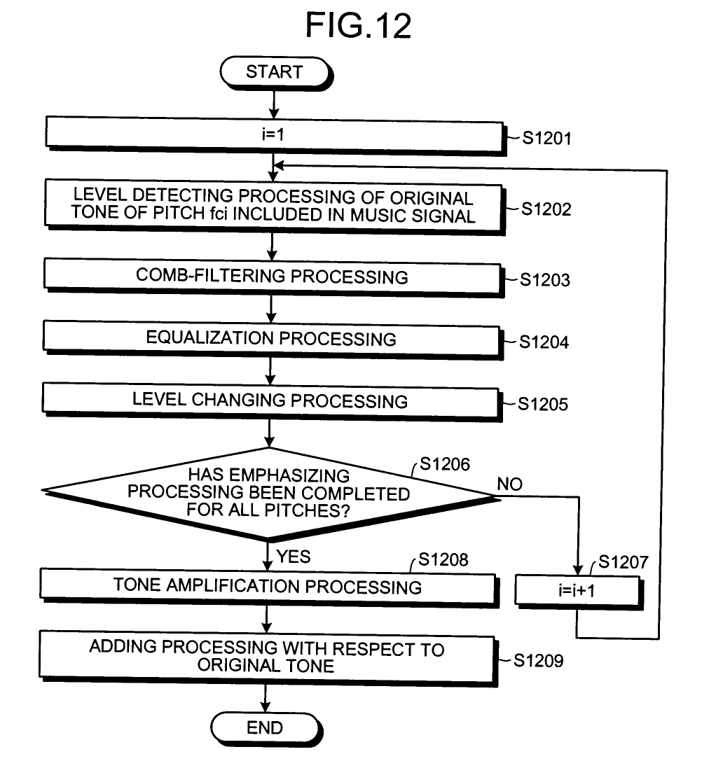

A procedure of tone emphasizing processing performed by the signal processor 302 configured as described above is described next. FIG. 12 is a flowchart of a procedure of tone emphasizing processing performed by the tone emphasizing unit. In the flowchart depicted in FIG. 12, i is set to 1 (i=1) to process, from the lowest frequency, the pitch fci to be emphasized (step S1201).

The level detecting unit 401 performs level detecting processing of the original tone of the pitch fci included in the music signal (step S1202). The comb filter unit 403 performs comb-filtering processing according to results of the level detection processing (step S1203).

After completion of the comb-filtering processing, the equalizing unit 404 performs equalization processing (step S1204). The level changing unit 402 performs level changing processing on the equalized music signal (step S1205).

After the processing has been completed through step S1205, the control unit 420 determines whether the emphasizing processing has been completed for all pitches (step S1206). If the emphasizing processing has not been completed for all pitches (step S1206: NO), i is incremented (i=i+1) to perform the emphasizing processing for the next pitch (step S1207), and the processing returns to step S1202 to perform the emphasizing processing for the pitch fci.

On the other hand, if it is determined at step S1206 that the emphasizing processing has been completed for all pitches (step S1206: YES), the amplifying unit 405 performs the amplification processing on the emphasized music signal (step S1208). Finally, the adding unit 406 adds the music signal amplified at step S1208 to the original tone (step S1209), thereby generating the emphasized tone signal, and the tone emphasizing processing ends.

The signal processor 302 includes the I/F 410 as depicted in FIGS. 4 to 6. The user uses the I/F 410 to set the pitch of the tone to be emphasized.

As described above, by using the stereo system according to the present example and performing the signal processing, a given tone can be emphasized more naturally without losing the balance of the upper harmonics. Further, even when the speaker cannot output low-frequency tones, at least the upper harmonics thereof are emphasized. Thus, the emphasis of the tone is perceived to be natural by the user.

The tone emphasizing method described in the present embodiment may be implemented by executing a prepared program on a computer such as a personal computer and a workstation. The program is stored on a computer-readable recording medium such as a hard disk, a flexible disk, a CD-ROM, an MO, and a DVD, read out from the recording medium, and executed by the computer. The program may be a transmission medium that can be distributed through a network such as the Internet.

1. (canceled)

2. (canceled)

3. (canceled)

4. (canceled)

5. (canceled)

6. (canceled)

7. (canceled)

8. (canceled)

9. (canceled)

10. A tone emphasizing device comprising:
a tone emphasizing unit that includes
a level detecting unit that detects a fundamental tone level of a tone of a given pitch included in an original tone reproduced by a data player;
an extracting unit that extracts frequency components of a fundamental tone and overtones from the original tone;
a frequency correcting unit that eliminates, from the frequency components extracted by the extracting unit, frequency components equal to or lower than the fundamental tone and frequency components equal to or higher than an overtone included in the tone of the given pitch; and
a level adjusting unit that adjusts, according to a result of detection by the level detecting unit, a level of the tone corrected by the frequency correcting unit;
an amplifying unit that amplifies to a desired level, the tone for which level has been adjusted by the level adjusting unit; and
an adding unit that adds to the original tone, the tone amplified by the amplifying unit.

11. The tone emphasizing device according to claim 10, wherein the level detecting unit detects the fundamental tone level of the tone of the given pitch based on a center frequency of the tone of the given pitch and a range of pitch.

12. The tone emphasizing device according to claim 10, wherein the extracting unit is configured with a comb filter that extracts frequency components of frequencies that are integer multiples of the frequency of the fundamental tone of the tone.

13. The tone emphasizing device according to claim 10, wherein the frequency correcting unit eliminates the frequency components and, amplifies or attenuates a given frequency range.

14. The tone emphasizing device according to claim 10, wherein
the tone emphasizing unit is provided in plurality, and the tone emphasizing units emphasize tones of different pitches,
the amplifying unit amplifies to a desired level, the tones for which level has been adjusted by the level adjusting units of the tone emphasizing units.

15. The tone emphasizing device according to claim 14, wherein
in place of the frequency correcting unit included in each tone emphasizing unit, the tone emphasizing device includes, downstream of the tone emphasizing units, a common frequency correcting unit that corrects frequencies of tones of different pitches, and
the level adjusting unit of each tone emphasizing unit adjusts the level of the tone components extracted by the extracting unit according to the result of detection by the level detecting unit.

16. A tone emphasizing method comprising:
a tone emphasizing step that includes
a level detecting step of detecting a fundamental tone level of a tone of a given pitch included in an original tone reproduced by a data player;
an extracting step of extracting frequency components of a fundamental tone and overtones from the original tone;
a frequency correcting step of eliminating, from the frequency components extracted at the extracting step, frequency components equal to or lower than the fundamental tone and frequency components equal to or higher than an overtone included in the tone of the given pitch; and
a level adjusting step of adjusting, according to a result of detection at the level detecting step, a level of the tone corrected at the frequency correcting step;
an amplifying step of amplifying to a desired level, the tone for which level has been adjusted at the level adjusting step; and
an adding step of adding to the original tone, the tone amplified at the amplifying step.

17. A computer-readable recording medium storing therein a tone emphasizing program that causes a computer to execute:
a tone emphasizing step that includes
a level detecting step of detecting a fundamental tone level of a tone of a given pitch included in an original tone reproduced by a data player;
an extracting step of extracting frequency components of a fundamental tone and overtones from the original tone;
a frequency correcting step of eliminating, from the frequency components extracted at the extracting step, frequency components equal to or lower than the fundamental tone and frequency components equal to or higher than an overtone included in the tone of the given pitch; and
a level adjusting step of adjusting, according to a result of detection at the level detecting step, a level of the tone corrected at the frequency correcting step;
an amplifying step of amplifying to a desired level, the tone for which level has been adjusted at the level adjusting step; and
an adding step of adding to the original tone, the tone amplified at the amplifying step.
